(19) United States
(12) Patent Application Publication
(10) Pub. No.: US 2013/0038375 A1
(43) Pub. Date: Feb. 14, 2013

(54) VOLTAGE LEVEL SHIFTER

(71) Applicants: Sung-Chieh LIN, Zhubei City (TW); Wei-Li LIAO, Taichung City (TW); Kuoyuan (Peter) HSU, San Jose, CA (US)

(72) Inventors: Sung-Chieh LIN, Zhubei City (TW); Wei-Li LIAO, Taichung City (TW); Kuoyuan (Peter) HSU, San Jose, CA (US)

(73) Assignee: TAIWAN SEMICONDUCTOR MANUFACTURING COMPANY, LTD., Hsinchu (TW)

(21) Appl. No.: 13/205,058

(22) Filed: Aug. 8, 2011

(51) Int. Cl. H03L 5/00

(52) U.S. Cl. 327/333

(57) ABSTRACT

A circuit includes a power switch and a level shifter. The level shifter has a node and an assistant circuit. The node is configured to control the power switch. The assistant circuitry is coupled to the node and configured for the node to receive a first voltage value through the assistant circuit. The first voltage value is different from a second voltage value of an input signal received by the level shifter.

### FIELD

The present disclosure is related to a voltage level shifter.

### BACKGROUND

In some current approaches, a level shifter shifts an input voltage provided by a “normal” voltage source to a higher output voltage provided by a “high” voltage source. The level shifter in some approaches requires a power-on sequence constraint in which the normal voltage from the normal voltage source reaches and remains at a stable voltage level before the high voltage from the high voltage source reaches its high voltage level. The applicants have recognized that the power-on sequence constraint is inconvenient in some situations as exemplarily detailed below.

If the power-on sequence is not in order, the high voltage from the high voltage source may reach its high voltage level before the normal voltage reaches its high voltage level. As a result, the output of the level shifter is in an unknown state, and, in some applications, the high voltage may unintentionally program an electrical fuse if the high voltage is ready but the output of level shifter is at a wrong state.

In some situations, the level shifter does not function well at lower operational voltages because at lower operational voltages the NMOS transistors in the level shifter conduct weakly. Increasing the size of pull down transistors in the level shifter can enable the level shifter to function better at lower operational voltages. This solution, however, would result in a larger die area for the level shifter. In many situations, increasing the size of the transistors is not feasible because the increased size would exceed the size limit specified by the design rules.

### BRIEF DESCRIPTION OF THE DRAWINGS

The details of one or more embodiments of the disclosure are set forth in the accompanying drawings and the description below. Other features and advantages will be apparent from the description, drawings, and claims.

FIG. 1 is a diagram of an exemplary circuit using a level shifter, in accordance with some embodiments.

FIG. 2 is a diagram of the level shifter in FIG. 1, in accordance with some embodiments.

Like reference symbols in the various drawings indicate like elements.

### DETAILED DESCRIPTION

Embodiments, or examples, illustrated in the drawings are disclosed below using specific language. It will nevertheless be understood that the embodiments and examples are not intended to be limiting. Any alterations and modifications in the disclosed embodiments, and any further applications of the principles disclosed in this document are contemplated as would normally occur to one of ordinary skill in the pertinent art. Reference numbers may be repeated throughout the embodiments, but they do not require that feature(s) of one embodiment apply to another embodiment, even if they share the same reference number.

Some embodiments have one or a combination of the following features and/or advantages. The circuit having a voltage level shifter is not constrained by a power-on sequence. The circuit can operate with an ultra low threshold voltage for a read operation, but the circuit size does not have to be enlarged. The circuit eliminates unintentional programming in various conditions including a condition during an electrostatic discharge (ESD) event.

### Exemplary Circuit

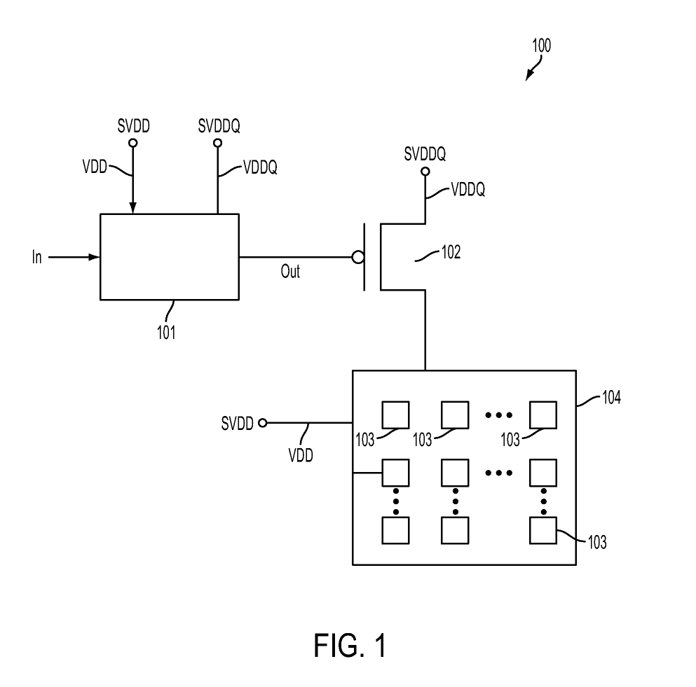

FIG. 1 is a diagram of a circuit 100 having a voltage level shifter 101, in accordance with some embodiments.

Voltage level shifter 101 receives operational voltage VDD from voltage source SVDD and provides an output voltage at output Out, based on voltage VDDQ provided by voltage source SVDDQ. For simplicity, the voltage at output Out is also called voltage VDDQ. In some embodiments, the high logic value of input In is voltage VDD. Based on the function of level shifter 101, when input In has a high logic value at the voltage level of voltage VDD, output Out is logically high at the voltage value of voltage VDDQ. In contrast, when input In has a low logic value at the voltage level of ground, output Out is also logically low at the voltage level of ground. In other words, level shifter 101 shifts voltage VDD to voltage VDDQ. In some embodiments, the shifting function of level shifter 101 is used in the program mode of electrical fuses (eFuses) 103 in eFuse array 104, because eFuses 103 are programmed based on voltage VDDQ. In the read mode, however, voltage VDDQ is electrically disconnected from eFuse array 104, and voltage VDD is used for the read operation. In some embodiments, voltage VDDQ is higher than voltage VDD. For example, voltage VDDQ is about 1.8 V, and voltage VDD is about 0.85 V.

eFuse memory array 104 includes eFuses 103. PMOS transistor 102 functions as a power switch. When transistor 102 is on, eFuses 103 operate in the program mode. But when transistor 102 is off, eFuses 103 operate in the read mode. For example, when output Out of level shifter 101 at the gate of PMOS transistor 102 is at a high logic value, transistor 102 is turned off. As a result, eFuse array 104 is electrically disconnected from voltage VDDQ, and eFuses 103 use voltage VDD for a read operation. In contrast, when output Out is at a low logic value, transistor 102 is turned on, and voltage VDDQ at the source of transistor 102 is passed to the drain of transistor 102 or to eFuse memory array 104. eFuses 103 then receive voltage VDDQ for use in the program operation.

### The Level Shifter

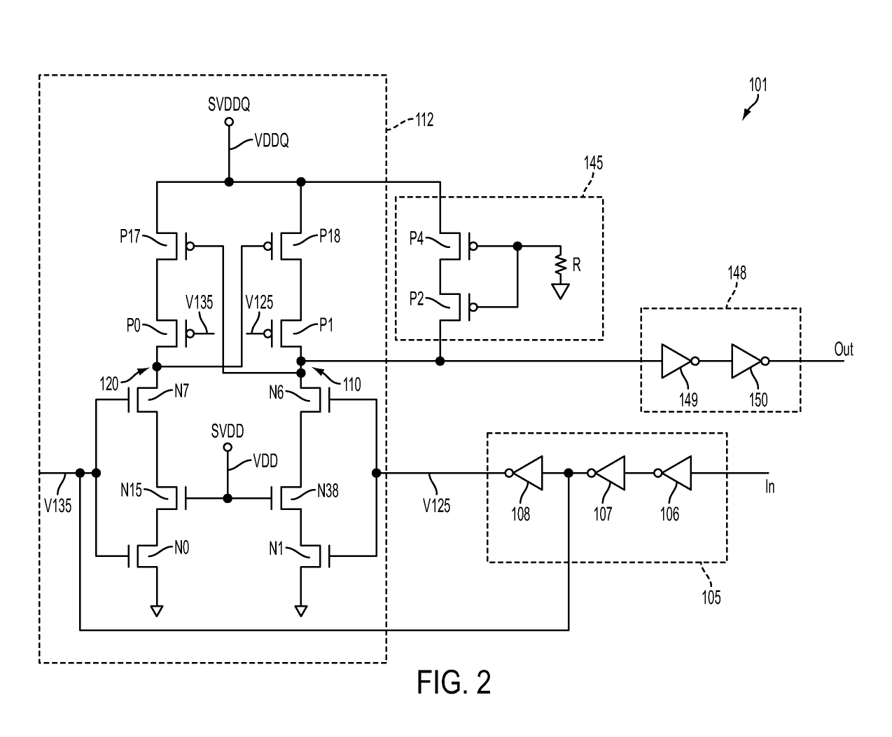

FIG. 2 is a diagram of level shifter or circuit 101, in accordance with some embodiments.

Input In of circuit 101 operates in the VDD domain because transistors in inverters 106, 107, and 108 are operated by voltage VDD. Input circuit 105 includes inverters 106, 107, and 108. Each of inverters 106, 107, and 108 functions as a buffer to provide additional current driving capabilities for signal V135 and signal V125. Based on the function of inverters 106, 107, and 108, signal V135 has the same phase as input In while signal V125 is out of phase with input In. In other words, when input In is logically low, signal V135 is also logically low, but signal V125 is logically high. Similarly, when input In is logically high, voltage 135 is logically high, but signal V125 is logically low. As a result, in this document, the logic value of input In is used interchangeably with the logic value of signal V135.

In contrast, output Out of circuit 101 operates in the VDDQ domain because transistors P17, P18, P4, P2, and transistors in inverters 149 and 150 are operated by voltage VDDQ. Output circuit 148 includes inverters 149 and 150. Each of inverters 149 and 150 functions as a buffer to increase the driving capabilities for output Out. Based on the function of inverters 149 and 150, output Out is in phase with the signal at node 110. As a result, in this document, the logic value of node 110 is used interchangeably with the logic value of output Out.

PMOS transistors P1 and P18 are commonly called the P side, and NMOS transistors N6, N38, and N1 are commonly called the N side of node 110. The P side tends to pull node 110 to voltage VDDQ at the source of PMOS transistors P18 while the N side tends to pull node 110 to ground at the source of NMOS transistor N1. Similarly, PMOS transistors P0 and P17 are commonly called the P side and NMOS transistors N7, N15, and N0 are commonly called the N side of node 120. The P side tends to pull node 120 to voltage VDDQ at the source of PMOS transistors P17 while the N side tends to pull node 120 to ground at the source of NMOS transistor N0.

Level shifting circuit 112 is symmetrical. The size and the type of transistors N0, N15, N7, P0, and P17 are the same as the size and the type of transistors, N1, N38, N6, P1, and P18, respectively. In other words, the left side of the N side is symmetrical with the right side of the N side, and the left side of the P side is symmetrical with the right side of the P side. As a result, the operation of circuit 101 with respect to node 110 is the same as the operation of circuit 101 with respect to node 120. Consequently, in this document, an explanation with respect to one side of circuit 101 (e.g., node 110) is applicable to the other side of circuit 101 (e.g., node 120).

The gates of NMOS transistors N15 and N38 are coupled together and configured to receive voltage VDDQ. As a result, transistors N15 and N38 are always on when circuit 101 is in operation.

NMOS transistors N1 and N6 are used to pull node 110 to a low logic value or ground at the source of transistor N1. PMOS transistors P1 and P18 are used to pull node 110 to a high logic value at the source of transistor P18. NMOS transistors N0 and N7 and PMOS transistors P0 and P17 function together with NMOS transistors N1 and N6 and PMOS transistors P1 and P18 such that the logic value at node 110 is the inverse of the logic value of node 120.

For example, when signal V125 at the gates of NMOS transistors N1 and N6 is logically high, transistors N1 and N6 are turned on. Transistors N1 and N6 being on, together with transistor N38 being on, pull node 110 to ground at the source of NMOS transistor N1. In other words, node 110 is logically low. At the same time, signal V135 at the gates of transistors N0 and N7 is logically low. As a result, transistors N0, N15, and N7 act as an open circuit. Signal V135 at the gate of PMOS transistor P0 is also logically low. As a result, PMOS transistor P0 is turned on. Node 110 at the gate of PMOS transistor P17 being logically low turns on transistor P17. Because transistors P0 and P17 are turned on, node 120 is pulled to a high logic value by voltage VDDQ at the source of PMOS transistor P17. Signal V125 being logically low at the gate of PMOS transistor P1 turns off transistor P1. As a result, transistors P1 and P18 act as an open circuit. Node 120 at the gate of PMOS transistor P18 being logically high turns off transistor P18, which further indicates transistor P18 acts as an open circuit.

Based on the above illustration, when signal V125 is logically high, node 110 is logically low and node 120 is logically high. In contrast, when signal V125 is logically low, node 110 is logically high and node 120 is logically low based on the symmetrical characteristic of circuit 112. For example, when signal V125 is logically low, transistors N1 and N6 are turned off. As a result, transistors N1, N38 and N6 act as an open circuit. At the same time, signal V135 at the gates of NMOS transistors N0 and N7 is logically high because signal V135 is the inverse of signal V125. Signal V135 being logically high causes transistors N0 and N7 to be turned on. Transistors N0, N15, and N7 being on pull node 120 to ground at the source of NMOS transistor N0. In other words, node 120 is logically low. Signal V125 at the gate of PMOS transistor P1 being logically low turns on transistor P1. Node 120 at the gate of PMOS transistor being logically low turns on transistor P18. Because transistors P18 and P1 are on, voltage VDDQ at the source of transistor P18 is passed to the drain of transistor P1. In other words, node 110 is logically high at the high voltage value of voltage VDDQ.

In effect, when input In is logically high, the high voltage value of voltage VDD at input In has been converted to the high voltage value of voltage VDDQ at output Out. Stated differently, circuit or level shifter 101 shifts the high voltage value of voltage VDD to the high voltage value of voltage VDDQ.

### The Assistant Circuit

Assistant circuit 145 includes PMOS transistors P2 and P4 that provide a condition for node 110 to default to a high voltage value when signal VDDQ is available. When node 110 is supposed to be logically low, transistors N1 and N6 are configured to pull node 110 to ground or a low logic value at the source of transistor N1.

The gates of PMOS transistors P2 and P4 are coupled together and are electrically connected to ground through resistor R. As a result, transistors P2 and P4 are always on when circuit 101 is in operation. Voltage VDDQ at the source of transistor P4, when available, together with transistors P4 and P2 being on, causes node 110 to be logically high at the voltage value of voltage VDDQ, if at least one of transistors N6 and N1 is either turned off or conducts weakly. As a result, in a power up situation, even if voltage VDDQ is available to circuit 101 before voltage VDD is available, node 110 is pulled to a high logic value of voltage VDDQ. Consequently, output Out is also logically high, and transistor 102 in circuit 100 is turned off. As a result, eFuses 103 are prevented from being unintentionally programmed.

For example, before being powered up, voltage sources SVDDQ and SVDD are both turned off. As a result, voltages VDDQ and VDD are both at 0 V, and nodes 110 and 120 are logically low. For a further illustration, voltage source SVDDQ having voltage VDDQ is turned on before voltage source SVDD having voltage VDD being turned on. Node 110 immediately receives voltage VDDQ through transistors P2 and P4 to have a high logic value. As a result, output Out is logically high, which causes transistor 102 to be off, and eFuses 103 to be in the read mode. Output Out being logically high prevents signal VDDQ from being passed to the drain of transistor 102. Effectively, eFuses 103 are electrically disconnected from voltage VDDQ, and are prevented from being unintentionally programmed by voltage VDDQ.

When voltage source SVDD having voltage VDD is turned on first, and signal VDD reaches its high voltage level, node 110 and thus output Out may be logically low, which can put eFuses 103 in the program mode. In some embodiments, the word line (not shown) and bit line (not shown) of the eFuse memory array 104, however, are turned on based on voltage VDD, and are designed to prevent eFuses 103 from being unintentionally programmed.

Effectively, circuit 100 functions as intended regardless of whether voltage VDDQ or voltage VDD is available first. In other words, circuit 100 is independent of the power up sequence of voltage VDDQ and voltage VDD.

In some embodiments, level shifter or circuit 101 having assistant circuit 145 operates as intended even at lower operational voltages VDD in a read operation. For example, in a read operation, eFuses 103 use voltage VDD, and output Out should be logically high to electrically disconnect voltage VDDQ from eFuses 103 as explained above with reference to FIG. 1. When voltage VDD is at a low voltage level, but is sufficient for a read operation, assistant circuit 145 together with voltage VDDQ causes node 110 to be logically high at the high voltage level of voltage VDDQ regardless of the condition of level shifting circuit 112. As a result, output Out is logically high, and voltage VDDQ at the source of transistor 102 in FIG. 1 is electrically disconnected from eFuses 103, and circuit 100 operates in the read mode as expected.

In contrast, without circuit 145, node 110 and/or node 120 could be in an unknown state if one of NMOS transistors N1, N6, N0 and N7 conducts weakly when voltage VDD has a lower voltage value. As a result, output Out of level shifter 101 could have a low logic value and thus enable a chance for eFuses 103 to be programmed by voltage VDDQ.

Effectively, circuit 101, in various embodiments, continues to function at lower voltages VDD, which is advantageous over other approaches. Additionally, in various embodiments, because circuit 145 is used in circuit 112, a larger size for transistors N6, N38, or N1 for circuit 112 is not used as a condition for circuit 112 to operate at lower operational voltages VDD as in other approaches.

Assistant circuit 145 coupled to node 110 is for illustration. Based on the symmetry of circuit 112, assistant circuit 145 may be coupled to node 120, and the operation of circuit 145 with respect to node 120 is similar to the operation of circuit 145 with respect to node 110 as explained in this document.

Circuit 101 being shown with two transistors P2 and P4 coupled in series is for illustration. One or more than two transistors and/or the transistors being connected in different connecting configurations to cause node 110 to be logically high when voltage VDDQ is available are within the scope of various embodiments.

In various situations, there may be a contention between the P side and the N side at node 110 because PMOS transistors P1, P18, P2, and P4 of the P side try to pull node 110 to the high voltage value VDDQ at the source of transistors P4 and P18. On the other hand, NMOS transistors N6, N38, and N1 of the N side try to pull node 110 to signal VSS (or ground) at the source of transistor N1. In some embodiments, transistors N6, N38, N1 are designed such that, when node 110 is supposed to be logically low, transistors N6, N38, and N1 have a strong driving capability to pull node 110 to a low logic value. Those of ordinary skill in the art will recognize that a transistor having a stronger driving capability when the transistor has a higher saturation current.

In some embodiments, transistors P2 and P4 function as a resistive device. The different number of transistors coupled in series and/or in parallel that generate a resistance is within the scope of various embodiments. The resistance of a transistor depends on the width and the length of the transistor. For example, a transistor having a longer length provides a higher resistance, and a transistor having a shorter length provides a lower resistance.

Resistors and/or resistive devices used in place of transistors P2 and/or P4 are within the scope of various embodiments. For example a resistor, a resistive device, a resistive network, etc., is used in place of transistors P2 and P4 so that node 110 is logically high when voltage VDDQ is available. The resistors include different types of resistors, such as poly resistors, OD resistors, etc. Similar to the situations in which transistors P2 and P4 are used, the resistors are designed such that when node 110 is intended to be logically low, the current flowing through the resistors is appropriate for the N side of circuit 101 to pull down node 110 to a low logic value. For example, if the resistance of the resistors is too high, NMOS transistors in the N side may need to be enlarged for node 110 to be pulled to a low logic value. In various embodiments, NMOS transistors are not enlarged, but maintained at a specified size so that the overall size of level shifter 101 remains at a specified size. The resistance value, however, is reduced. In some embodiments, the values of the resistors and/or transistors (e.g., P2, P4, N1, N38, N36, etc.) are selected based on simulation. For example, the resistance values and/or the transistor sizes are simulated such that level shifter 101 continues to function as a level shifter, but node 110 is default to be logically high when voltage VDDQ is available and is pulled to a low logic value for circuit 101 functions as a level shifter.

In some embodiments, PMOS transistors P17, P18, P0, P1 P4, and P2, transistors in inverters 149 and 150, and NMOS transistors N7, N6, N15, and N38 are “high” voltage transistors because they operate based on voltage VDDQ that is higher than the traditional operational voltage VDD. As a result, in some embodiments, PMOS transistors P17, P18, P0, P1 P4, and P2, transistors in inverters 149 and 150, and NMOS transistors N7, N6, N15, and N38 are selected from the input/output (IO) transistors of a memory platform. In contrast, NMOS transistors N0, N1, and transistors in inverters 106, 107, and 108 are “normal” or “low” voltage transistor because they operate based on a traditional voltage VDD. As a result, in some embodiments, NMOS transistors N0, N1, and transistors in inverters 106, 107, and 108 are selected from the memory core transistors of the memory platform.

Level shifting circuit 112 is used for illustration. Other level shifting circuitries and/or other implementations of circuit 112 are within the scope of various embodiments. For example, in some embodiments, one or a combination of pairs of transistors P0/P1, N6/N7, and N15/N38 are not included in circuit 112. The types of transistors (e.g., normal transistors or high voltage transistors) are selected accordingly. For another example, the P side of circuit 112 includes PMOS transistors P18 and P17, but does not include PMOS transistors P0 and P1. The N side of circuit 112 includes NMOS transistors N0 and N1, but does not include NMOS transistors N7, N6, N15, and N38. In this configuration, transistors N0 and N1 are high voltage or VDDQ transistors (e.g. versus normal or VDD transistors).

A number of embodiments have been described. It will nevertheless be understood that various modifications may be made without departing from the spirit and scope of the disclosure. For example, the various transistors being shown as a particular dopant type (e.g., N-type or P-type Metal Oxide Semiconductor (NMOS or PMOS)) are for illustration purposes. Embodiments of the disclosure are not limited to a particular type. Selecting different dopant types for a particular transistor is within the scope of various embodiments. The low or high logic level (e.g., Low or High) of the various signals used in the above description is also for illustration purposes. Various embodiments are not limited to a particular level when a signal is activated and/or deactivated. Selecting different levels is within the scope of various embodiments.

In some embodiments, a circuit comprises a power switch and a level shifter. The level shifter has a node and an assistant circuit. The node is configured to control the power switch. The assistant circuitry is coupled to the node and is configured for the node to receive a first voltage value through the assistant circuitry. The first voltage value is different from a second voltage value of an input signal received by the level shifter.

In some embodiments, a level shifter comprises a level shifting circuit and an assistant circuit. The level shifting circuit has a first P side symmetrical with a second P side, a first N side symmetrical with a second N side, a first node formed between the first N side and the first P side, and a second node formed between the second N side and the second P side. The level shifting circuit is configured to receive an input signal having a first logical high voltage value and generate an output signal having an output logical high voltage value different from the first logical high voltage value. The assistant circuit is coupled to the second node and configured to receive a second logical high voltage value and, based on the second logical high voltage value, generate a logic value at the second node.

In some embodiments, a circuit comprises a first PMOS transistor, a second PMOS transistor, a third PMOS transistor, a fourth PMOS transistor, a first NMOS transistor, a second NMOS transistor, a third NMOS transistor, a fourth NMOS transistor, a first node, a second node, and an assistant circuitry. The first PMOS transistor has a first P drain, a first P source, and a first P gate. The second PMOS transistor has a second P drain, a second P source, and a second P gate. The third PMOS transistor has a third P drain, a third P source, and a third P gate. The fourth PMOS transistor has a fourth P drain, a fourth P source, and a fourth P gate. The first NMOS transistor has a first N drain, a first N source, and a first N gate. The second NMOS transistor has a second N drain, a second N source, and a second N gate. The third NMOS transistor has a third N drain, a third N source, and a third N gate. The fourth NMOS transistor has a fourth N drain, a fourth N source, and a fourth N gate. The first node is formed at the third PMOS drain and the third NMOS drain. The second node is formed at the fourth PMOS drain and the fourth NMOS drain. The assistant circuit is coupled to the second node, is configured to receive a first voltage value and, based on the first voltage value, generates a second voltage value at the second node. The first PMOS source and the second PMOS source are configured to receive the first voltage value. The first PMOS drain is coupled to the third PMOS source. The first PMOS gate is coupled to the second node. The second PMOS drain is coupled to the fourth PMOS source. The second PMOS gate is coupled to the first node. The third PMOS gate is configured to receive a first signal. The fourth PMOS gate is configured to receive a second signal. The second signal is an inverse logic of the first signal. The third NMOS source is coupled to the first NMOS drain. The third NMOS gate is configured to receive the first signal. The fourth NMOS source is coupled to the second NMOS drain. The fourth NMOS gate is configured to receive the second signal. The first NMOS gate is configured to receive the first signal. The second NMOS gate is configured to receive the second signal.

The above illustrative description includes exemplary steps, but the steps are not necessarily performed in the order described. Steps may be added, replaced, changed order, and/or eliminated as appropriate, in accordance with the spirit and scope of disclosed embodiments.

What is claimed is:

1. A circuit comprising:
a power switch; and
a level shifter having
a node configured to control the power switch,
a first voltage terminal for supplying a first voltage value, and
a level shifting circuit coupled to the node and configured for the node to receive the first voltage value in response to a second, different voltage value of an input signal received by the level shifter; and
an assistant circuit permanently electrically connecting the first voltage terminal to the node.

2. The circuit of claim 1, wherein the assistant circuit includes at least one PMOS transistor electrically coupled to the node and configured to receive the first voltage value.

3. The circuit of claim 2, wherein transistors in the at least one PMOS transistor are coupled in series and/or in parallel when the at least one PMOS transistor has more than one transistor.

4. The circuit of claim 2, wherein a gate of a PMOS transistor of the at least one PMOS transistor is configured to receive a low logic value.

5. The circuit of claim 1, wherein the assistant circuit includes at least one resistive device coupled to the node and configured to receive the first voltage value.

6. The circuit of claim 1, further comprising at least one inverter coupled to the node.

7. The circuit of claim 1, wherein the power switch is configured to control an electrical fuse.

8. A level shifter comprising:
a level shifting circuit having
a first P side symmetrical with a second P side,
a first N side symmetrical with a second N side, the level shifting circuit configured to receive an input signal having a first logical high voltage value and generate an output signal having an output logical high voltage value different from the first logical high voltage value;
a first node between the first N side and the first P side; and
a second node between the second N side and the second P side; and
an assistant circuit coupled to the second node and configured to receive a second logical high voltage value and, based on the second logical high voltage value, generate a logic value at the second node.

9. The level shifter of claim 8, wherein a signal at the second node is configured to switch operational modes of a power switch.

10. The level shifter of claim 8, wherein a signal at the second node is configured to switch operational modes of an electrical fuse.

11. The level shifter of claim 8, wherein the assistant circuit includes a resistive device coupled to the second node and configured to receive the second logical high voltage value.

12. The level shifter of claim 8, wherein the assistant circuit includes a PMOS transistor coupled to the second node and configured to receive the second logical high voltage value.

13. The level shifter of claim 8, wherein
the first P side includes a first PMOS transistor electrically coupled to the first node, configured to receive the second logical high voltage value, and a gate of the first PMOS transistors coupled to the second node;
the second P side includes a second PMOS transistor electrically coupled to the second node, configured to receive the second logical high voltage value, and a gate of the second PMOS transistor coupled to the first node;
the first N side includes a first NMOS transistor electrically coupled to the first node, configured to receive a reference voltage, and a first gate of the first NMOS transistor configured to receive a first signal; and
the second N side includes a second NMOS transistor electrically coupled to the second node, configured to receive the reference voltage, and a second gate of the second NMOS transistor configured to receive a second signal that is an inverse logic of the first signal.

14. The level shifter of claim 13, wherein
the first P side further includes a third PMOS transistor coupled between the first PMOS transistor and the first node, a gate of the third PMOS transistor configured to receive the first signal; and
the second P side further includes a fourth PMOS transistor coupled between the second PMOS transistor and the second node, a gate of the fourth PMOS transistor configured to receive the second signal.

15. The level shifter of claim 14, wherein
the first N side further includes a third NMOS transistor coupled between the first node and the first NMOS transistor, a gate of the third NMOS transistor configured to receive the first signal; and
the second N side further includes a fourth NMOS transistor coupled between the second node and the second NMOS transistor, a gate of the fourth NMOS transistor configured to receive the second signal.

16. The level shifter of claim 15, wherein
the first N side further includes a fifth NMOS transistor coupled between the third NMOS transistor and the first NMOS transistor; and
the second N side further includes a sixth NMOS transistor coupled between the fourth NMOS transistor and the second NMOS transistor.

17. The level shifter of claim 13, wherein
the first N side further includes a third NMOS transistor coupled between the first node and the first NMOS transistor, a gate of the third NMOS transistor configured to receive the first signal; and
the second N side further includes a fourth NMOS transistor coupled between the second node and the second NMOS transistor, a gate of the fourth NMOS transistor configured to receive the second signal.

18. The level shifter of claim 17, wherein
the first N side further includes a fifth NMOS transistor coupled between the third NMOS transistor and the first NMOS transistor; and
the second N side further includes a sixth NMOS transistor coupled between the fourth NMOS transistor and the second NMOS transistor.

19. The level shifter of claim 13, wherein
the first N side further includes a third NMOS transistor coupled between the first node and the first NMOS transistor; and
the second N side further includes a fourth NMOS transistor coupled between the second node and the second NMOS transistor, a gate of the fourth NMOS transistor and a gate of the third NMOS transistor configured to receive a high logic value.

20. A circuit comprising:
a first PMOS transistor having a first P drain, a first P source, and a first P gate;
a second PMOS transistor having a second P drain, a second P source, and a second P gate;
a third PMOS transistor having a third P drain, a third P source, and a third P gate;
a fourth PMOS transistor having a fourth P drain, a fourth P source, and a fourth P gate;
a first NMOS transistor having a first N drain, a first N source, and a first N gate;
a second NMOS transistor having a second N drain, a second N source, and a second N gate;
a third NMOS transistor having a third N drain, a third N source, and a third N gate;
a fourth NMOS transistor having a fourth N drain, a fourth N source, and a fourth N gate;
a first node formed at the third PMOS drain and the third NMOS drain;
a second node formed at the fourth PMOS drain and the fourth NMOS drain; and
an assistant circuit,
wherein
the assistant circuit is coupled to the second node, configured to receive a first voltage value and, based on the first voltage value, generates a second voltage value at the second node;
the first PMOS source and the second PMOS source are configured to receive the first voltage value;
the first PMOS drain is coupled to the third PMOS source;
the first PMOS gate is coupled to the second node;
the second PMOS drain is coupled to the fourth PMOS source;
the second PMOS gate is coupled to the first node;
the third PMOS gate is configured to receive a first signal;
the fourth PMOS gate is configured to receive a second signal;
the second signal is an inverse logic of the first signal;
the third NMOS source is coupled to the first NMOS drain;
the third NMOS gate is configured to receive the first signal;
the fourth NMOS source is coupled to the second NMOS drain;
the fourth NMOS gate is configured to receive the second signal;
the first NMOS gate is configured to receive the first signal; and
the second NMOS gate is configured to receive the second signal.
